(19) United States
(12) Patent Application Publication
(10) Pub. No.: US 2024/0021701 A1
(43) Pub. Date: Jan. 18, 2024

(54) ELECTRONIC ESD PROTECTION DEVICE

(71) Applicant: STMicroelectronics (Tours) SAS, Tours (FR)

(72) Inventors: Aurelie ARNAUD, Saint-Cyr-Sur-Loire (FR); Julien LADROUE, Monnaie (FR)

(73) Assignee: STMicroelectronics (Tours) SAS, Tours (FR)

(21) Appl. No.: 18/349,041

(22) Filed: Jul. 7, 2023

(30) Foreign Application Priority Data
Jul. 18, 2022 (FR) 2207307

(51) Int. Cl. H01L 29/66; H01L 29/866; H01L 29/861

(52) U.S. Cl. CPC H01L 29/66106; H01L 29/866; H01L 29/8611; H01L 29/66128; H01L 29/66136; H01L 21/02315

(57) ABSTRACT

The present description concerns a method for manufacturing a protection device against overvoltages, comprising the following successive steps: a) epitaxially forming, on a semiconductor substrate, a semiconductor layer; b) submitting the upper surface of the semiconductor layer to a fluorinated-plasma process; and c) forming an electrically-insulating layer over and contacting the upper surface of the semiconductor layer.

### CROSS-REFERENCE TO RELATED APPLICATION(S)

This application claims the priority benefit of French patent application number 2207307, filed on Jul. 18, 2022, entitled “Dispositif électronique de protection ESD” which is hereby incorporated by reference to the maximum extent allowable by law.

### TECHNICAL FIELD

The present disclosure generally concerns electronic devices, and more particularly, electronic devices of protection against overvoltages, for example against electrostatic discharges or ESDs.

### DESCRIPTION OF THE RELATED ART

Different devices of prevention and protection against electrostatic discharges are known.

### BRIEF SUMMARY

There is a use for improving the performance of current devices of protection against electrostatic discharges.

An embodiment provides a method for manufacturing a protection device against overvoltages, comprising the following steps, in the order:
a) epitaxially forming on a semiconductor substrate, a semiconductor layer;
b) submitting the upper surface of the semiconductor layer to a fluorinated-plasma process; and
c) forming an electrically-insulating layer over and contacting the upper surface of the semiconductor layer.

According to an embodiment, the method comprises, before step a), a step of forming of a first semiconductor region of the conductivity type opposite to that of the substrate, in an upper portion of the substrate.

According to an embodiment, the PN junction between the first semiconductor region and the substrate forms a Zener diode of the protection device.

According to an embodiment, the method comprises, after step a) and before step b), a step of forming a second semiconductor region of the conductivity type opposite to that of the semiconductor layer, in an upper portion of the semiconductor layer.

According to an embodiment, the PN junction between the semiconductor layer and the second semiconductor region constitutes a diode of the protection device.

According to an embodiment, the semiconductor layer has the conductivity type opposite to that of the substrate.

According to an embodiment, the semiconductor layer has a doping level between 1·10¹³ atoms/cm³ and 1·10¹⁵ atoms/cm³.

According to an embodiment, the plasma applied in step b) is a carbon fluoride plasma.

According to an embodiment, the plasma applied in step b) is an inductive-coupling plasma.

According to an embodiment, the electrically-insulating layer is a silicon oxide layer.

According to an embodiment, the substrate and the semiconductor layer are made of silicon.

According to an embodiment, the substrate has an N-type doping and the semiconductor layer has a P-type doping.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1A, FIG. 1B, FIG. 1C, FIG. 1D, FIG. 1E, FIG. 1F, and FIG. 1G show steps of an implementation mode of a method of manufacturing a device of protection against electrostatic discharges; and

FIG. 2 is a graphic representation illustrating an example of variation of parasitic capacitances present in the device illustrated in FIG. 1G.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the various possible applications of the described ESD protection circuits have not been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front,” “back,” “top,” “bottom,” “left,” “right,” etc., or to relative positional qualifiers, such as the terms “above,” “below,” “upper,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10%, and preferably within 5%.

ESD protection devices having a vertical structure, comprising a vertical stack of semiconductor regions of distinct doping types for example defining ESD protection diodes connected in series or in anti-series, topped with an insulating layer, for example, based on an oxide, are here particularly considered.

ESD protection devices with a small parasitic capacitance are particularly considered. In this case, the upper insulating layer is generally in contact with a very lightly doped semiconductor layer. The method of forming the insulating layer may cause the trapping of electric charges at the interface between the very lightly doped semiconductor layer and the insulating layer. These charges result in degrading the performance of the ESD protection device and particularly in increasing its parasitic capacitance, in particular for low-frequency signals.

According to an aspect of an embodiment, it is provided to treat the surface of the upper semiconductor layer by means of a fluorinated plasma before the forming of the insulating layer, to limit the trapping of charges at the interface with the insulating layer and thus decrease the parasitic capacitance of the device, particularly for low-frequency signals.

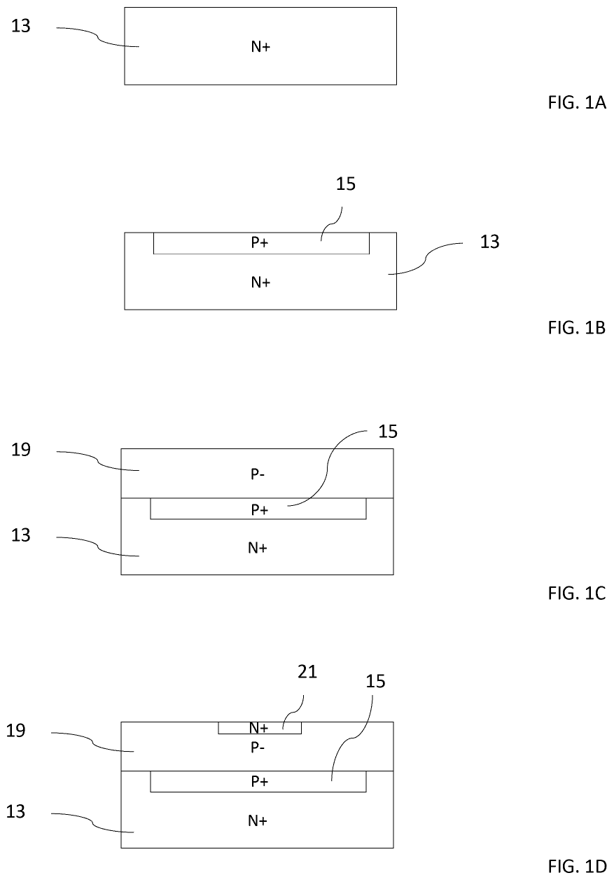

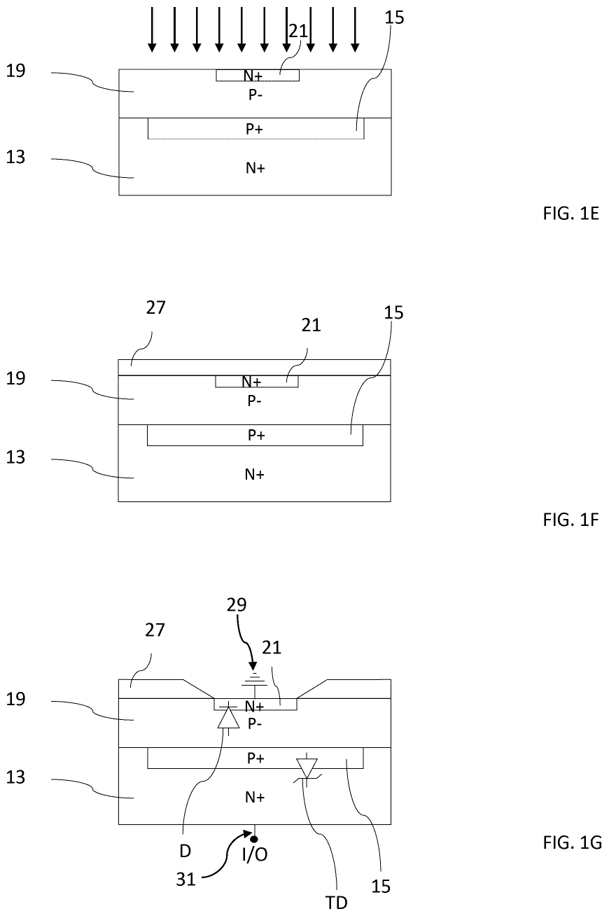

FIG. 1A, FIG. 1B, FIG. 1C, FIG. 1D, FIG. 1E, FIG. 1F, and FIG. 1G are cross-section views illustrating successive steps of an implementation mode of a method of manufacturing an example of a device of protection against electrostatic discharges.

FIG. 1A shows an initial structure comprising a substrate 13.

Substrate 13 is for example made of a semiconductor material of a first conductivity type, for example, of type N. As an example, substrate 13 is heavily N-type doped, for example with a doping level in the range from 2·10¹⁹ atoms/cm³ to 7·10¹⁹ atoms/cm³. Substrate 13 is for example made of silicon.

FIG. 1B illustrates a structure obtained at the end of a step of forming, in an upper portion of substrate 13, a semiconductor area 15 having a conductivity type opposite to that of the substrate.

Area 15 is for example formed in substrate 13 so that it is flush with a surface, the upper surface in the orientation of FIG. 1B, of substrate 13.

Area 15 is for example formed by implantation of dopant elements on the upper surface side of substrate 13. As an example, the implantation is located on a portion only of the surface of substrate 13. Thus, in this example, area 15 extends over a portion only of the surface of substrate 13. The doping level, of area 15 is for example in the range from 1·10¹⁷ atoms/cm³ to 1·10¹⁹ atoms/cm³. The thickness of area 15 is for example in the range from 1 μm to 4 μm.

In the rest of the disclosure, the upper surface of a structure or of a layer, in the orientation of FIG. 1B, is considered as being the front side and the lower surface of the structure or of a layer, in the orientation of FIG. 1B, is considered as being the back side.

FIG. 1C illustrates a structure obtained at the end of a step of forming of a semiconductor layer 19 on the front side of the structure illustrated in FIG. 1B.

During this step, layer 19 is formed over the entire upper surface of the structure, that is, it is formed all over the upper surface of substrate 13 and of area 15. Layer 19 for example has a substantially constant thickness across the entire surface of the structure. Layer 19 has, for example, a thickness in the range from 8 μm to 15 μm, for example equal to approximately 12 μm.

Layer 19 is for example of the same conductivity type as area 15, for example, of type P. As an example, the doping level of layer 19 is lower than that of area 15. Layer 19 is preferably very lightly doped. The doping level of layer 19 is for example in the range from 1·10¹³ atoms/cm³ to 1·10¹⁵ atoms/cm³. Thus, the material of the layer is preferably strongly resistive. As an example, the material of layer 19 has an electric conductivity in the range from 10 Ω·cm to 200 Ω·cm, or even greater than 200 Ω·cm.

Layer 19 is for example made of the same material as substrate 13, for example, of silicon. As an example, layer 19 is formed by epitaxy on top of and in contact with the upper surface of the structure of FIG. 1B.

FIG. 1D illustrates a structure obtained at the end of a step of forming, in an upper portion of layer 19, a second semiconductor area 21 of a conductivity type opposite to that of layer 19, for example, of type N.

Area 21 is for example formed in layer 19 so that the front side of area 21 is flush with the front side of layer 19. Area 21 is for example located vertically in line with area 15. As an example, the center of area 21 is vertically aligned with the center of area 15.

Area 21 is for example formed by implantation of dopant elements on the upper surface side of layer 19. As an example, the implantation is located on a portion only of the surface of substrate 13. Thus, in this example, area 21 extends over a portion only of layer 19. As an example, area 21 extends, in the plane of the front side of the structure, over a surface area smaller than the surface area of area 15.

The doping level of area 21 is for example equivalent to that of substrate 13. As an example, the doping level of area 21 is in the range from 1·10¹⁹ atoms/cm³ to 1·10²⁰ atoms/cm³. The thickness of area 21 is for example in the range from 0.8 μm to 4 μm.

FIG. 1E illustrates a step of treatment of the upper surface of layer 19 by means of a fluorinated plasma. During this step, fluorine atoms are implanted in a surface portion of layer 19, for example, at the extreme surface of layer 19.

As an example, the plasma is a carbon fluoride plasma, the carbon atoms enabling to avoid an etching of layer 19 during the treatment. As an example, the plasma is made of carbon tetrafluoride (CF4), of octafluorocyclobutane (C4F8), or of trifluoromethane (CHF3).

As an example, the plasma treatment is performed over the entire surface of the front side of the structure.

Preferably, during this step, an inductive-coupling plasma is used. As an example, the substrate biasing power allowing the acceleration of ions at the surface is greater than 50 W, for example, greater than 100 W.

FIG. 1F illustrates a structure obtained at the end of a step of deposition of an electrically-insulating layer or passivation layer 27 on the front side of the structure illustrated in FIG. 1E.

Layer 27 is for example deposited over the entire upper surface of the structure. Layer 27 for example has a substantially constant thickness across its entire surface. As an example, the thickness of insulating layer 27 is in the range from 1 μm to 4 μm, for example, equal to approximately 2 μm.

As an example, layer 27 is made of an oxide, for example, a silicon oxide, for example made of USG (“Undoped Silicate Glass”), of TEOS (tetraethyl orthosilicate), or of a thermal oxide. As an example, layer 27 is formed by chemical vapor deposition or CVD such as a plasma-enhanced chemical vapor deposition (PECVD) or a low-pressure chemical vapor deposition (LPCVD). This deposition is for example followed by an anneal of layer 27.

FIG. 1G illustrates a structure obtained at the end of a step of local etching of layer 27 from the structure illustrated in FIG. 1F.

During this step, a through opening is for example formed in layer 27 and thus exposes a portion of area 21.

As an example, the etching is performed so that the sides of the opening are oblique and the opening narrows along with its depth. In other words, in FIG. 1G, the opening is narrower at the level of the front side of area 21 than at the level of the front side of layer 27.

As an example, the etching is performed by photolithography and then etching.

In the structure illustrated in FIG. 1G, the horizontal PN junction between area 15 and substrate 13, forms a Zener diode TD, for example a diode known under trade name Transil, having its anode formed by area 15 and its cathode corresponding to substrate 13. The respective doping levels of substrate 13 and of area 15 define the avalanche voltage of zener diode TD, and thus the turn-on voltage of the ESD protection device.

The horizontal PN junction between layer 19 and area 21 forms a diode D having its cathode corresponding to area 21 and its anode corresponding to layer 19. In this embodiment, diode D and Zener diode TD are connected in anti-series.

As an example, the area 21 of device 1G is intended to be connected to ground 29, and substrate 13 is intended to be connected to an input/output pad 31 (I/O) of a device to be protected.

The protection device may comprise connection metallizations, not shown, respectively in contact with the upper surface of area 21 (through the opening formed in layer 27) and with the lower surface of substrate 13, enabling to connect the device to an external device to be protected.

The device may further comprise a third diode (not shown) forward-connected between ground 29 and input/output pad 31. This third diode is for example formed by the PN junction between layer 19 and substrate 13. In case of a positive overvoltage on pad 31, the Zener diode starts an avalanche and the overvoltage is discharged to ground 29 via diode D, which then is forward-conducting. In case of a negative overvoltage on pad 31, the overvoltage is discharged to ground 29 via the third diode (not shown), which then is forward-conducting.

An advantage of the method described in relation with FIGS. 1A to 1G is that the fluorine-based plasma treatment (FIG. 1E) implemented before the forming of insulating layer 27 (FIG. 1F) enables to compensate for the traps present at the interface between layer 19 and layer 27 and thus limit the trapping of electric charges at the interface between layer 19 and layer 27. This enables to decrease the parasitic capacitance of the ESD protection device.

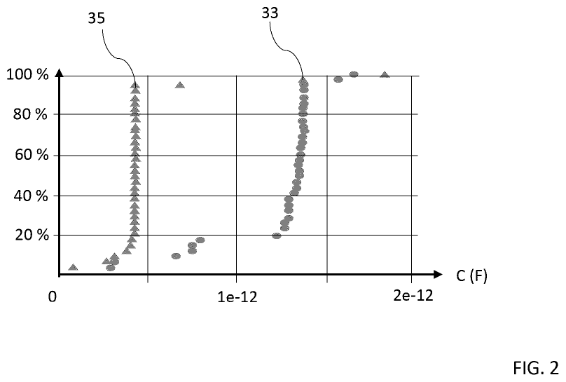

FIG. 2 is a graphic representation illustrating an example of variation of parasitic capacitances present in the device illustrated in FIG. 1G.

More particularly, FIG. 2 illustrates the variation of the distribution (in %, in ordinates) of the parasitic capacitance C of diode D (in Farads (F), in abscissas) with or without application of the plasma treatment described in relation with FIG. 1E.

The graph of FIG. 2 comprises two curves:
a first curve 33 representing the distribution of the parasitic capacitance and of the junction capacitance of diode D when the plasma treatment of FIG. 1E is not implemented; and
a second curve 35 representing the distribution of the parasitic capacitance and of the junction capacitance of diode D when the plasma treatment of FIG. 1E is implemented.

These curves show that the provision of the fluorinated plasma treatment enables to decrease the parasitic capacitance by approximately 66%. In this example, in the absence of the plasma treatment, the measured average parasitic capacitance of diode D is approximately 1.5 pF. In the presence of the plasma treatment, the measured average parasitic capacitance is approximately 0.5 pF.

An advantage of the present embodiment is that the implantation of fluorine atoms at the surface of layer 19 enables to limit the trapping of parasitic electric charges (and particularly of positive parasitic charges in the case of a lightly P-type doped layer 19) at the interface with layer 27.

Various embodiments and variants have been described. Those skilled in the art will understand that certain features of these various embodiments and variants may be combined, and other variants will occur to those skilled in the art. In particular, the described embodiments are for example not limited to the examples of dimensions and of materials mentioned hereabove.

Further, the described embodiments are not limited to the specific example of ESD protection structure described in relation with FIG. 1G, but more generally apply to any ESD protection device integrated inside and on top of a semiconductor substrate.

Finally, the practical implementation of the described embodiments and variations is within the abilities of those skilled in the art based on the functional indications given hereabove.

A Method for manufacturing a protection device against overvoltage, may be summarized as including the following steps, in the order: a) epitaxially forming, on a semiconductor substrate (13), a semiconductor layer (19); b) submitting the upper surface of the semiconductor layer (19) to a fluorinated-plasma process; and c) forming an electrically-insulating layer (27) over and contacting the upper surface of the semiconductor layer (19).

The method may include, before step a), a step of forming a first semiconductor region (15) of the conductive type opposite to that of the substrate (13), in a upper portion of the substrate (13).

The PN junction between the first semiconductor region (15) and the substrate (13) may constitute a Zener diode (TD) of the protection device.

The method may include, after step a) and before step b), a step of forming a second semiconductor region (21) of the conductive type opposite to that of the semiconductor layer (19), in a upper portion of the semiconductor layer (19).

The PN junction between the semiconductor layer (19) and the second semiconductor region (21) may constitute a diode (D) of the protection device.

The semiconductor layer (19) may have the conductive type opposite to that of the substrate (13).

The semiconductor layer (19) may have a doping level between 1·10¹³ atomes/cm³ and 1·10¹⁵ atomes/cm³.

The plasma applied in step b) may be a carbon fluoride plasma.

The plasma applied in step b) may be an inductive-coupling plasma.

The electrically-insulating layer (27) may be a silicon oxide layer.

The substrate (13) and the semiconductor layer (19) may be made of silicon.

The substrate (13) may have a N-type doping and the semiconductor layer (19) may have a P-type doping.

In one embodiment, a method includes forming a semiconductor layer having a first surface opposite a second surface along a first direction, the semiconductor layer having a first thickness along the first direction and a first width along a second direction that is transverse to the first direction; forming a first semiconductor area in the semiconductor layer, the first semiconductor area having a first surface that is coplanar with the first surface of the semiconductor layer, the first semiconductor area having a second thickness along the first direction that is smaller than the first thickness and a second width along the second direction that is smaller than the first width; forming a semiconductor layer on the first surface of the first semiconductor area and the first surface of the semiconductor layer, the semiconductor layer having a third width along the second direction that is greater than the second width; forming a second semiconductor area in the semiconductor layer, the second semiconductor area having a fourth width that is smaller than the second width, the second semiconductor area having a first surface that is coplanar with a first surface of the semiconductor layer and a second surface that is between the first surface of the second semiconductor area and the first surface of the first semiconductor area; and forming a fluorinated-plasma implanted in the first surface of semiconductor layer. These features and relationships can be seen in FIGS. 1A-1G and the related description.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for manufacturing a device, comprising:
forming, on a semiconductor substrate having a first conductivity type, a semiconductor layer;
forming a fluorinated-plasma in an upper surface of the semiconductor layer during a fluorinated-plasma treatment process; and
forming an electrically-insulating layer over and contacting the upper surface of the semiconductor layer.

2. The method of claim 1, comprising, before the forming the semiconductor layer, forming a first semiconductor region of a second conductivity type opposite to the first conductivity type of the substrate, in an upper portion of the substrate.

3. The method of claim 2, comprising forming a first PN junction between the first semiconductor region and the substrate.

4. The method of claim 3, wherein the first PN junction is a Zener diode.

5. The method according to claim 3, comprising, after the forming the semiconductor layer and before the forming the fluorinated-plasma in the upper surface of the semiconductor layer, forming a second semiconductor region of the first conductivity type in the upper portion of the semiconductor layer.

6. The method of claim 5, comprising forming a PN junction between the semiconductor layer and the second semiconductor region constitutes a diode of the protection device.

7. The method according to claim 1, wherein the semiconductor layer has the second conductivity type.

8. The method according to claim 1, wherein the semiconductor layer has a doping level between 1·10¹³ atoms/cm³ and 1·10¹⁵ atoms/cm³.

9. The method according to claim 1, wherein the fluorinated-plasma is a carbon fluoride plasma.

10. The method according to claim 1, wherein the fluorinated-plasma is an inductive-coupling plasma.

11. The method according to claim 1, wherein the electrically-insulating layer is a silicon oxide layer.

12. The method according to claim 1, wherein the substrate and the semiconductor layer include silicon.

13. The method according to claim 1, wherein the substrate has a N-type doping and the semiconductor layer has a P-type doping.

14. A method comprising:
forming a semiconductor layer having a first surface opposite a second surface along a first direction, the semiconductor layer having a first thickness along the first direction and a first width along a second direction that is transverse to the first direction;
forming a first semiconductor area in the semiconductor layer, the first semiconductor area having a first surface that is coplanar with the first surface of the semiconductor layer, the first semiconductor area having a second thickness along the first direction that is smaller than the first thickness and a second width along the second direction that is smaller than the first width;
forming a semiconductor layer on the first surface of the first semiconductor area and the first surface of the semiconductor layer, the semiconductor layer having a third width along the second direction that is greater than the second width;
forming a second semiconductor area in the semiconductor layer, the second semiconductor area having a fourth width that is smaller than the second width, the second semiconductor area having a first surface that is coplanar with a first surface of the semiconductor layer and a second surface that is between the first surface of the second semiconductor area and the first surface of the first semiconductor area; and
forming a fluorinated-plasma implanted in the first surface of semiconductor layer.

15. The method according to claim 14, comprising forming an electrically-insulating layer on the semiconductor layer and the second semiconductor area.

16. The method according to claim 14, wherein the second semiconductor layer is positioned centrally in relation to the first semiconductor layer along the first direction.

17. The method according to claim 15, comprising etching through the electrically-insulating layer to expose the second semiconductor area.

18. The method according to claim 14, wherein the semiconductor substrate and the second semiconductor area have a first conductivity type and the first semiconductor area and semiconductor layer have a second conductivity type opposite the first conductivity type.

19. A method for manufacturing a device, comprising:
forming a first semiconductor area in a semiconductor substrate, the semiconductor substrate having a first conductivity type and the first semiconductor area having a second conductivity type opposite the first conductivity type;
forming, on the semiconductor substrate, a semiconductor layer having the second conductivity type;
forming a second semiconductor area in the semiconductor layer, the second semiconductor area having the first conductivity type, the second semiconductor area being positioned centrally in relation to the first semiconductor area along a first direction and having a first width along a second direction transverse to the first direction;
forming a plasma in a first surface of the semiconductor layer and in a first surface of the second semiconductor area;
forming an electrically-insulating layer on the semiconductor layer; and
etching a gap in the electrically-insulating layer, the gap being positioned centrally in relation to the first semiconductor area along the first direction and having a second width along the second direction that is at least as wide as the first width.

20. The method of claim 19, wherein a first side of the gap extends along a third direction that is transverse to both the first direction and the second direction.
